(19) United States
(12) Patent Application Publication
(10) Pub. No.: US 2005/0068744 A1
(43) Pub. Date: Mar. 31, 2005

(54) Case for removable hard drive

(76) Inventor: James-Jyh Chian Huang, Cerritos, CA (US)

Correspondence Address: BRUCE H. TROXELL, SUITE 1404, 5205 LEESBURG PIKE, FALLS CHURCH, VA, 22041, US

(21) Appl. No.: 10/673,423

(22) Filed: Sep. 30, 2003

(51) Int. Cl. H05K 5/00

(52) U.S. Cl. 361/724

(57) ABSTRACT

A case for removable hard drive includes a main body, a back cover, and more than one hard disk holders. The hard disk holder is configured for connecting and carrying a hard disk. The main body is a three-dimensional frame made of a metal material by way of stamping, and provided between two lateral sides with a plurality of slide rails, into which the bard disk holders are slid to locate thereat. The main body and the back cover are detachably connected together through a fastening structure. While the main body is produced to have a uniform specification, the back cover that has relatively small volume and simple structure may be fabricated according to different specifications of hard disks to be held in the main body, so that the whole case for removable hard drive may be produced at reduced cost and used in a more flexible manner.

### FIELD OF THE INVENTION

The present invention relates to a case for removable hard drive, and more particularly to a case for removable hard drive having a detachable back cover to allow holding of hard disks of different specifications with a uniform main body.

### BACKGROUND OF THE INVENTION

Computers have been widely used by people to handle many things in their work and daily life. With the constant progress and development in the information technology, various types of mass storage, that is, hard disks, have been researched and developed to largely reduce the selling price of hard disks to a level that is acceptable by most consumers. Therefore, it is a trend, particularly in many large-scale businesses, to use the hard disk as a databank to substitute for the conventional paper-based data that require a considerably large space to store them. However, a prerequisite to set up a computerized databank is to have sufficient data storage capacity. Typically, several mass storages are needed to provide necessary space for storing data. For some big-scale businesses or special trades, such as Internet Service Providers (ISP) or big-scale merchandisers, it is possible to use hundreds or even thousands of hard disks to meet the actual need. To enable convenient maintenance and replacement of the large number of hard disks, there is developed a case for removably holding multiple hard disks therein, and the hard disks that are removably held in such case are referred to as a removable hard drive. FIG. 1 is a perspective view of a commercially available conventional case for removable hard drive, which mainly includes a main body (A), and more than one hard disk holder (B). The hard disk holders (B) are configured for connecting and carrying a hark disk each, and the main body (A) is a three-dimensional frame made of a metal material by way of, for example, stamping. The main body (A) is provided between two lateral sides with a plurality of slide rails (C), into which the hard disk holders may be slid to locate thereat. The main body (A) is pre-formed on a rear wall with a plurality of openings (D) in the same number and at the same intervals as that of the slide rails (C). Each of the openings (D) is adapted for mounting a control circuit board (G) thereto, so that the hard disk holder (B) having a hard disk mounted thereto may be directly inserted from a front end of the main body (A) into a corresponding slide rail (C) and be locked in place after having been pushed to a predetermined position in the main body (A). In the above-mentioned locked position, connectors (not shown) provided at a rear side of the hard disk responsible for data transmission and power supply may be respectively connected to a data connecting terminal (E) and a power supply terminal (F) on the control circuit board (G). The hard disk may therefore be quickly inserted into and drawn out of the main body (A) for change purpose. There are electric connections provided between the data connecting terminal (E) and the power supply terminal (F). To enable reliable operation of the hard disks held in the case, the main body (A) is provided at one side with cooling fans (H) to effectively reduce a working temperature of the hard disk, and detection and warning means (I) to automatically emit a warking signal when any of the cooling fans (H) is detected as failed, so that an operator is reminded of proper and timely repair, maintenance, or replacement of the failed cooling fan (H).

A disadvantage of the above-structured conventional case for removable hard drive is that the main body (A) is integrally made of a metal material by way of stamping, and the openings (D) preformed on the rear wall of the main body (A) have fixed shape and size, making the main body (A) available for holding only hard disks of the same specification. As a matter of fact, the currently developed hard disks not only permit expansion in capacity, but also have constantly changed new specifications. For instance, there are several different interfaces available for the current hard disks, including IDE (Integrated Drive Electronics), SCSI (Small Computer System/Standard Interface), Serial-ATA interface, and Fibre Channel interface. FIGS. 2A to 2C sequentially illustrate the IDE, the SCSI, and the Serial-ATA interfaces for hard disks. It can be seen from FIGS. 3A to 3C, these interfaces have connecting terminals of quite different configurations and sizes, and even different locations. Therefore, the main body (A) of the conventional case for removable hard drive may be used to hold only one type of hard disks depending on the openings (D) provided on the rear wall thereof. A manufacturer must simultaneously prepare at least three types of main bodies (A) each having a different type of openings (D) to produce cases for removable hard drives of three different specifications. This would inevitably cause inconvenience and confusion in the manufacturer stock and warehouse management, preventing the manufacturing cost from effective reduction. Once the half-finished or finished products of the main body (A) fail to meet any newly developed specification for the hard disks, they shall become completely useless and form only a burden to the manufacturer.

It is therefore tried by the inventor to develop an improved case for removable hard drive to eliminate the above-mentioned provlems.

### SUMMARY OF THE INVENTION

A primary object of the present invention is to provide an improved case for removable hard drive to effectively solve the problems of stock and warehouse management encountered by the conventional case for removable hard drive.

To achieve the object, the case for removable hard drive according to an embodiment of the present invention includes a main body, a back cover, and more than one hard disk holder. The hard disk holder is configured for connecting and carrying a hard disk. The main body is a three-dimensional frame made of a metal material by way of stamping, and provided between two lateral sides with a plurality of slide rails, into which the hard disk holders are slid to locate thereat. The main body and the back cover are detachably connected together through a fastening structure. While the main body is produced to have a uniform specification, the back cover that has relatively small volume and simple structure may be fabricated according to different specifications of hard disks to be held in the main body. In this manner, the problems of difficult stock and warehouse management may be solved.

Another object of the present invention is to provide the above-structured case for removable hard drive, so that the whole case for removable hard drive may be produced at reduced cost and used in a more flexible manner by using the back cover of different specifications with the uniform main body. A manufacturer may produce only the back covers to meet any hard disk of new specification developed in the future while keeps producing the main body in the same uniform specification.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a conventional case for removable hard drive;

FIGS. 2A, 2B and 2C shows three connecting terminals of different specifications;

FIG. 3 is an exploded perspective view of a case for removable hard drive according to an embodiment of the present invention;

FIG. 4 is an assembled perspective view of FIG. 4; and

FIG. 5 shows the back cover of the case for removable hard drive of FIG. 4 is replaced with another one having openings with shape and size different from that of FIG. 4.

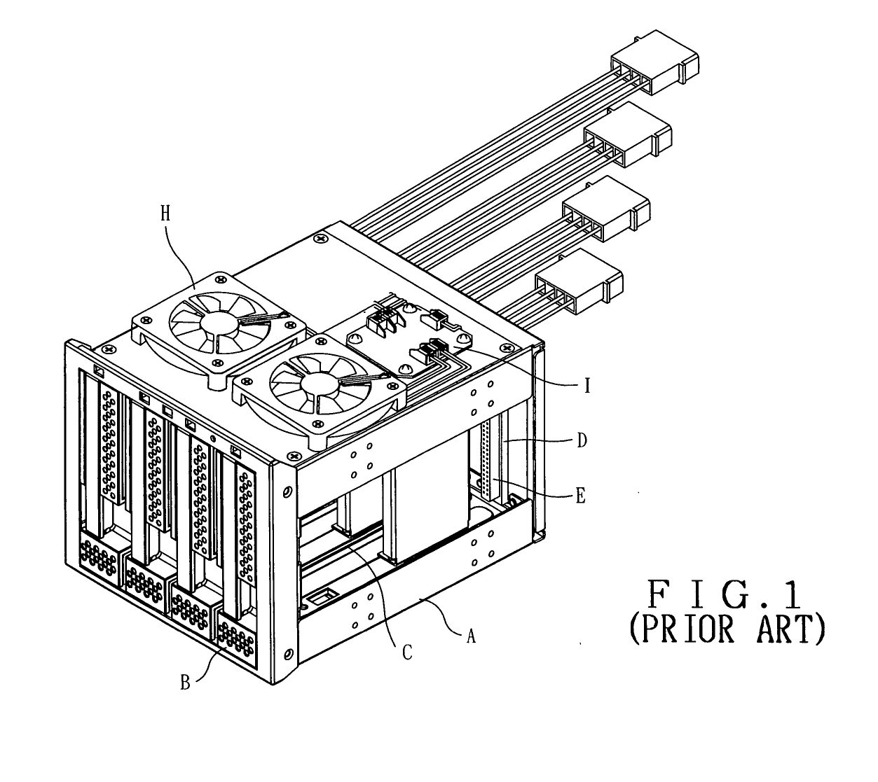

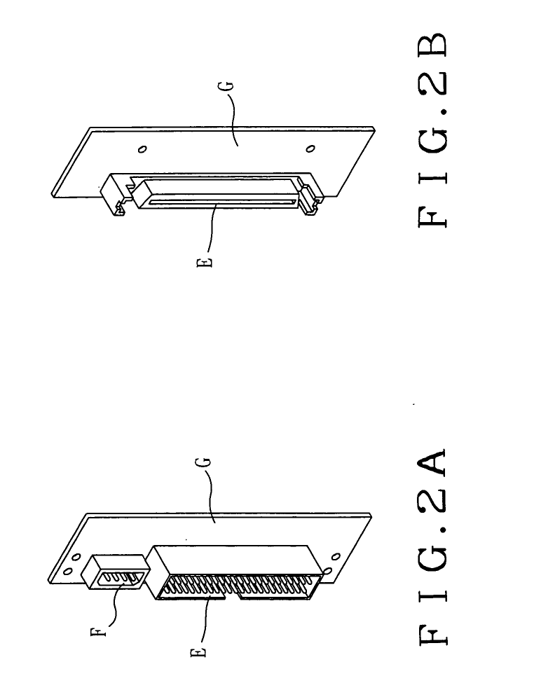

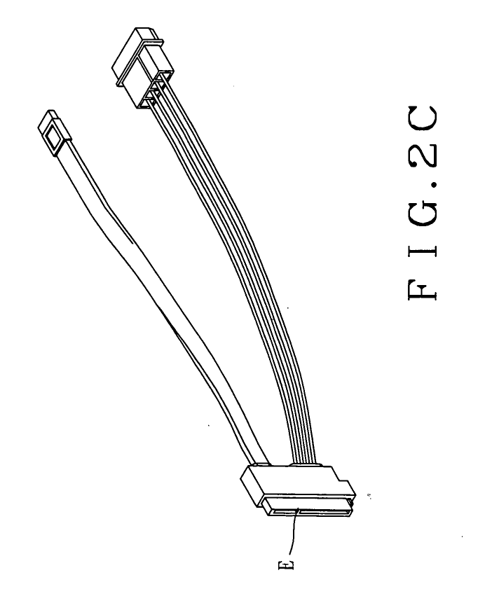

### DETAILED DESCRIPTION OF THE PREFERRED EMBODIMENTS

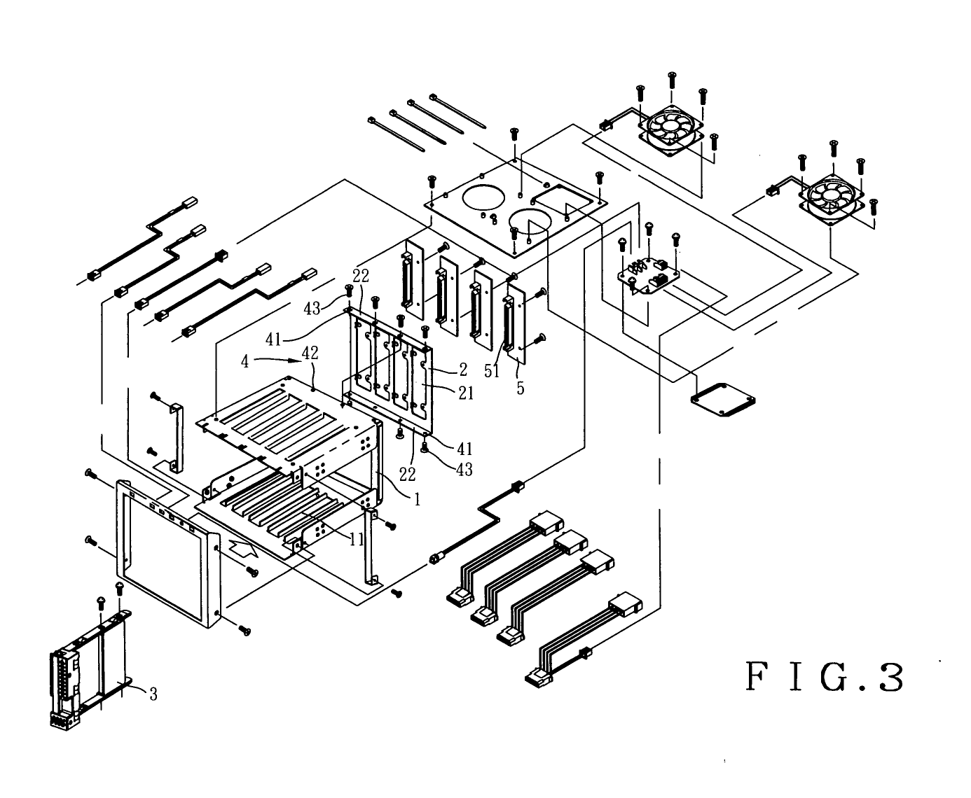

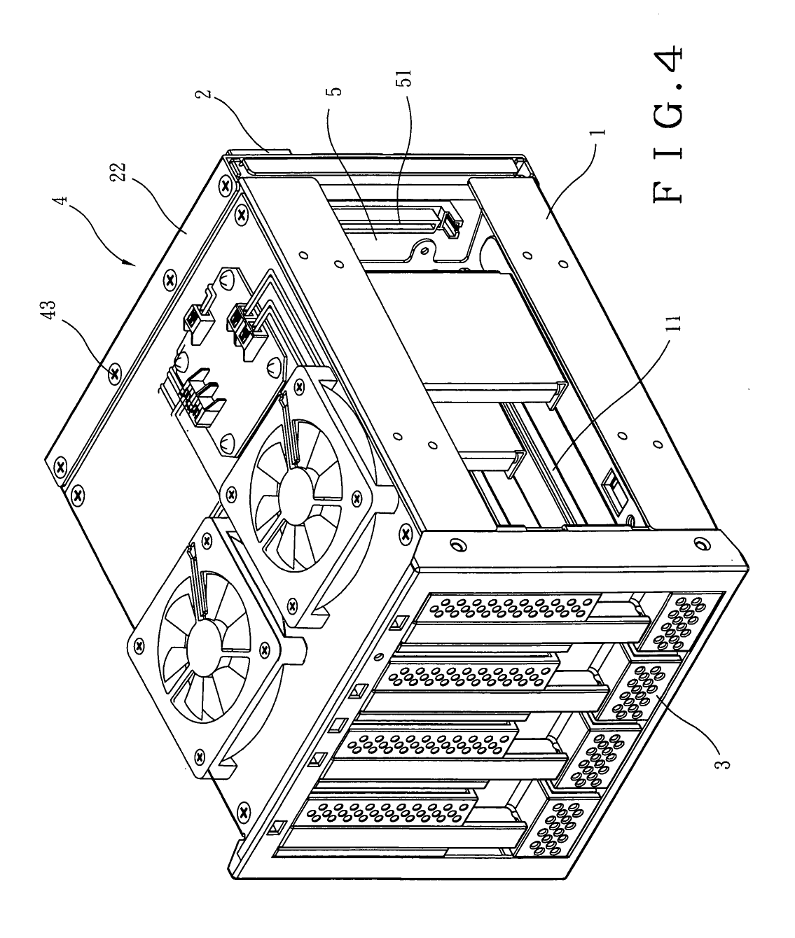

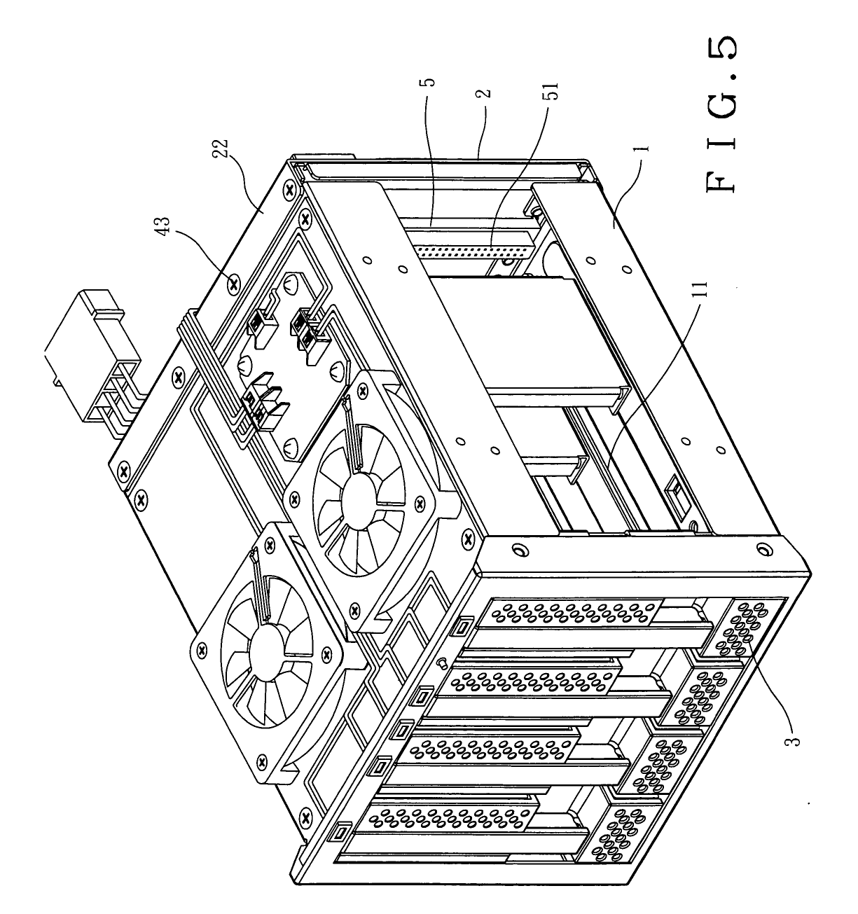

Please refer to FIGS. 3 and 4 that are exploded and assembled perspective views, respectively, of a case for removable hard drive according to an embodiment of the present invention. As shown, the case for removable hard drive of the present invention mainly includess a main body (1), a back cover (2) and more than one hard disk holder (3). The hard disk holder (3) is configured for connecting and carrying a hard disk. The main body (1) is a three-dimensional frame made of a metal material by way of, for example, stamping. The main body (1) is provided between two lateral sides with a plurality of slide rails (11), into which the hard disk holders (3) may be separately slid to locate thereat. The back cover (2) is provided with a plurality of openings (21) in the same number as that of the slide rails (11). Each of the openings (21) on the back cover (2) is adapted for mounting a control circuit board (5) thereto. The control circuit board (5) has a connecting terminal (51) provided thereon, and there are electric connectings provided between two adjacent control circuit boards (5). The back cover (2) is detachably connected to the main body (1) by means of fastening structures (4). With the above structural design, a manufacturer may separately mass-produce the main bodies (1) in a uniform specification, and the back covers (2) having differently shaped and sized openings (21) corresponding to the specifications of hard disks to be held in the case for removable hard drive. By coupling back covers (2) having differently shaped and sized openings (21) with the main bodies (1), cases for removable hard drive available for holding hard disks of different specifications may be conveniently provided, as shown in FIGS. 4 and 5. The back cover (2) has smaller volume and simpler structure, requires less material, and is easier to manufacture, when compared with the main body (1). Therefore, the separate manufacturing of the back cover (2) and the main body (1) for the case for removable hard drive according to the present invention may effectively solve the problems existed in the conventional structure, including difficulties in stock and warehouse management.

The back ccover (2) is a U-shaped member having two sidewalls (22) to enable optimal fixing of the back cover (2) to the main body (1). The fastening structures (4) for fixing the back cover (2) to the main body (1) may be of any acceptable means known in the prior art, such as locking with screws, coupling through snap fittings, etc., they are not discussed in details herein. In the illustrated embodiment of the present invention, the fastening structures are screws and screw holes. More specifically, the U-shaped back cover (2) is provided at the two sidewalls (22) with mounting holes (41), and the main body (1) is provided at corresponding positions with threaded holes (42). To mount the back cover (2) to a rear side of the main body (1), simply attach the two sidewalls (22) to two outer surfaces of the main body (1) and use screws (43) to sequentially thread through the mounting holes (41) on the back cover (2) and the threaded holes (42) on the main body (1), so that the back cover (2) is locked to the main body (1).

Since each type of connecting terminal (5) has a uniform and standardized specification, it is possible for the manufacturer to produce the back cover (2) for a main body (1) to hold hard disks of a particular specification simply by changing an overall length of the two sidewalls (22) to allow adjustment of positions of the connecting terminals (51) fixed on the openings (21) of the back covers (2), so that the connecting terminals (51) may be optimally coupled with terminals on the hard disks.

The present invention has been described with a preferred embodiment thereof and it is understood that many changes and modifications in the described embodiment, such as changes in the fastening structures for the back cover and the main body, can be carried out without departing from the scope and the apirit of the invention that is intended to be limited only by the appended claims.

In brief, in the case for removable hard drive according to the present invention, the back cover and the main body are separately produced and may be detachably connected together with a fastening structure according to actual need to effectively enable convenient stock and warehouse management, as well as good expansion capacity to meet new specifications of the hard disks in the future. Thus, the present invention may be produced at largely and effectively reduced cost to be more competitive in the market.

1. A case for removable hard drive, comprising a main body, a back cover, and more than one hard disk holder; said hard disk holders being configured for connecting and carrying a hard disk each; said main body being a three-dimensional frame, and provided between two lateral sides with a plurality of slide rails, into which said hard disk holders are separately slid to locate thereat; said back cover being provided with a plurality of openings corresponding to said slide rails; and said main body and said back cover being detachably connected together with a fastening structure.

2. The case for removable hard drive as claimed in claim 1, wherein said back cover is a U-shaped member.

3. The case for removable hard drive as claimed in claim 2, wherein said fastening structure comprises locking with screws.

4. The case for removable hard drive as claimed in claim 3, wherein said fastening structure includes mounting holes provided on two sidewalls of said U-shaped back cover, and threaded holes provided on said main body at corresponding positions.

5. The case for removable hard drive as claimed in claim 1, wherein said main body is made of a metal material by way of stamping.

6. The case for removable hard drive as claimed in claim 1, wherein said back cover is made of a metal material by way of stamping.

7. The case for removable hard drive as claimed in claim 1, wherein each of said openings provided on said back cover is adapted for mounting a control circuit board thereto, and said control circuit board having a connecting terminal provided thereon.

8. The case for removable hard drive as claimed in claim 7, wherein electric connections are provided between any two of said control circuit boards that are adjacent to each other.
